(19) United States
(12) Patent Application Publication
(10) Pub. No.: US 2025/0096147 A1
(43) Pub. Date: Mar. 20, 2025

(54) OVERLAY MARK

(71) Applicant: MACRONIX International Co., Ltd., Hsinchu (TW)

(72) Inventors: Chiung Jung Tu, Hsinchu County (TW); Chih-Hao Huang, Hsinchu Country (TW); Yu-Lin Liu, Hsinchu Country (TW); Chin-Cheng Yang, Kaohsiung City (TW)

(73) Assignee: MACRONIX International Co., Ltd., Hsinchu (TW)

(21) Appl. No.: 18/470,421

(22) Filed: Sep. 20, 2023

(51) Int. Cl. H01L 23/544

(52) U.S. Cl. CPC H01L 23/544; H01L 2223/54426

(57) ABSTRACT

An overlay mark includes a previous layer mark and a current layer mark. The previous layer mark includes a plurality of first work zones. Each first working zone includes a first sub-region and a second sub-region, wherein the first sub-region is closer to a center point of the previous layer mark than the second sub-region. The previous layer mark includes a first mark and an auxiliary mark respectively in the first sub-region and the second sub-region of each first working zone. The current layer mark includes a plurality of second working zones. Each second working zone includes a first sub-region and a second sub-region. The current layer mark includes a second mark disposed in the second sub-region of each second working zone. The overlay mark may be applied in the process of manufacturing a 3D NAND flash memory with high capacity and high performance.

### BACKGROUND

### Technical Field

The embodiment of the disclosure relates to a semiconductor device, and in particular to an overlay mark.

### Description of Related Art

The photolithographic process is a patterning technique widely used in semiconductor processes. The photolithographic process usually calculates the overlay error by the overlay mark. However, if the overlay mark is a trench, the planarization of the conductive material filling into the trench may suffer from the load effect. In addition, the uneven or asymmetric surface profile of the conductive layer filling into the trench may also make it difficult to calculate the correct overlay error.

### SUMMARY

The embodiment of the present disclosure provides an overlay mark, which may reduce or prevent the load effect, and may be used to calculate the correct overlay error.

An overlay mark of the embodiment of the present disclosure includes a previous layer mark and a current layer mark. The previous layer mark includes a plurality of first work zones, and each first work zone includes a first sub-region and a second sub-region. The first sub-region is closer to a center point of the previous layer mark than the second sub-region. The previous layer mark includes a first mark and an auxiliary mark. The first mark is disposed in the first sub-region of each first work zone. The auxiliary mark is disposed in the second sub-region of each first work zone. The current layer mark includes a plurality of second work zones, and each second work zone includes a first sub-region and a second sub-region. The first sub-region of the current layer mark overlaps with the first sub-region of the previous layer mark, and the second sub-region of the current layer mark overlaps with the second sub-region of the previous layer mark. The current layer mark includes a second mark disposed in the second sub-region of each second work zone.

Based on the above, the overlay mark of the embodiment of the present disclosure may reduce or prevent the load effect, and may be used to calculate the correct overlay error.

### BRIEF DESCRIPTION OF THE DRAWINGS

FIG. 1A is a top view of a previous layer mark of an overlay mark according to the embodiment of the present disclosure.

FIG. 1B is a top view of a current layer mark of an overlay mark according to the embodiment of the present disclosure.

FIG. 1C is a top view of an overlay mark according to the embodiment of the present disclosure.

FIG. 2 is a schematic diagram of an overlay mark in a partial region and its signal wave during measurement according to the embodiment of the present disclosure.

FIG. 3A to FIG. 3E are respectively an enlarged schematic diagram of a first overlay pattern in a partial region according to various embodiments of the present disclosure.

FIG. 4A and FIG. 4B are respectively an enlarged schematic diagram of an auxiliary mark in a partial region according to various embodiments of the present disclosure.

FIG. 5 is an enlarged schematic diagram of a second overlay pattern in a partial region according to the embodiment of the present disclosure.

FIG. 6A is a top view of a previous layer mark of an overlay mark according to another embodiment of the present disclosure.

FIG. 6B is a top view of a current layer mark of an overlay mark according to another embodiment of the present disclosure.

FIG. 6C is a top view of an overlay mark according to another embodiment of the present disclosure.

FIG. 7 is a schematic diagram of an overlay mark in a partial region and its signal wave during measurement according to another embodiment of the present disclosure.

FIG. 8A to FIG. 8F are schematic cross-sectional views of a manufacturing process of a memory device according to the embodiment of the present disclosure.

FIG. 9A and FIG. 9B are schematic cross-sectional views along lines I-I′ and II-II′ of FIG. 1C, respectively.

### DESCRIPTION OF THE EMBODIMENTS

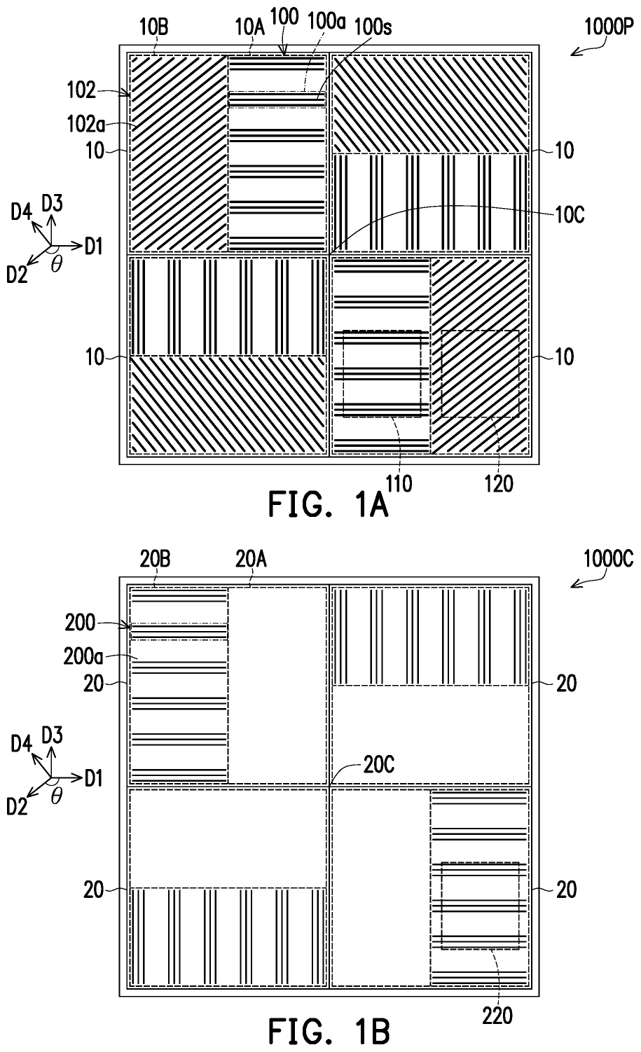

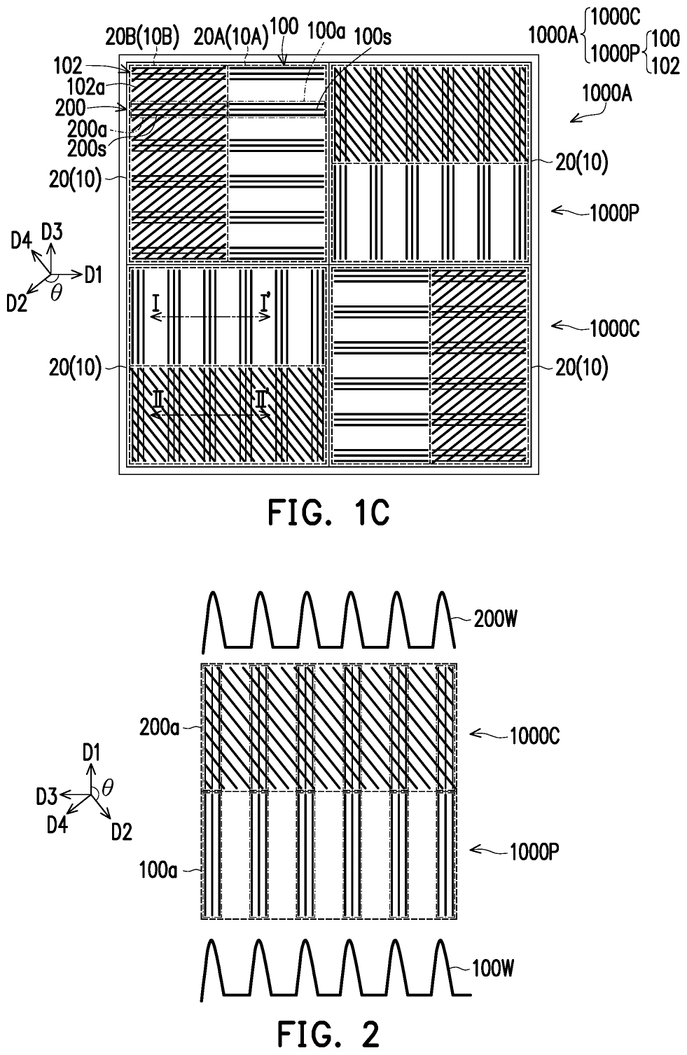

FIG. 1A is a top view of a previous layer mark 1000P of an overlay mark 1000A according to the embodiment of the present disclosure. FIG. 1B is a top view of a current layer mark 1000C of an overlay mark 1000A according to the embodiment of the present disclosure. FIG. 1C is a top view of an overlay mark 1000A according to an embodiment of the present disclosure.

Referring to FIG. 1A to FIG. 1C, an overlay mark 1000A of the embodiment of the present disclosure includes a previous layer mark 1000P and a current layer mark 1000C. Referring to FIG. 1A, the previous layer mark 1000P includes a plurality of first work zones 10. In FIG. 1A, the previous layer mark 1000P includes four first work zones 10, but the disclosure is not limited thereto. The four first work zones 10 are adjacent to one another. Each first work zone 10 includes a first sub-region 10A and a second sub-region 10B. The first sub-region 10A is closer to a center point 10C of the previous layer mark 1000P than the second sub-region 10B. In other words, the first sub-regions 10A of the previous layer mark 1000P may be adjacent to one another and may be arranged to form a windmill-like shape, and the second sub-regions 10B of the previous layer mark 1000P may be separated from each other by the first sub-regions 10A.

Referring to FIG. 1A, the previous layer mark 1000P includes a plurality of first marks 100. The first mark 100 is respectively disposed in the first sub-region 10A of each first work zone 10. In the embodiment, the previous layer mark 1000P includes four first marks 100, and they are adjacent to one another. The first mark 100 of the previous layer mark 1000P is used to calculate the overlay error with the second mark 200 of the current layer mark 1000C (shown in FIG. 1B). Each first mark 100 includes a plurality of first overlay patterns 100a extending along the first direction D1. In FIG. 1A, each first mark 100 includes six first overlay patterns 100a. However, the embodiment of the present disclosure is not limited thereto. Each first mark 100 may include more first overlay patterns 100a.

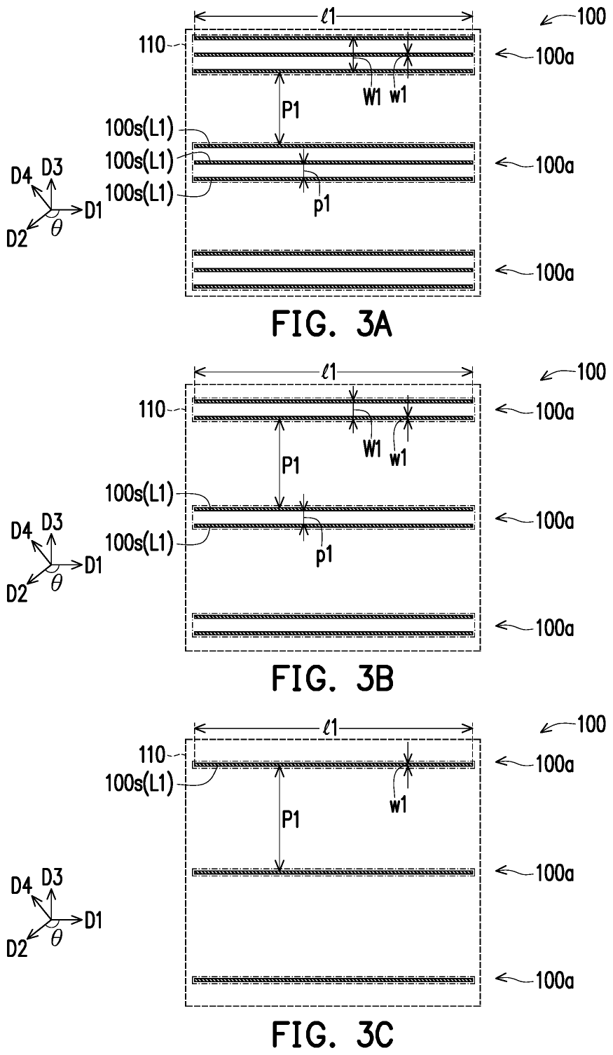

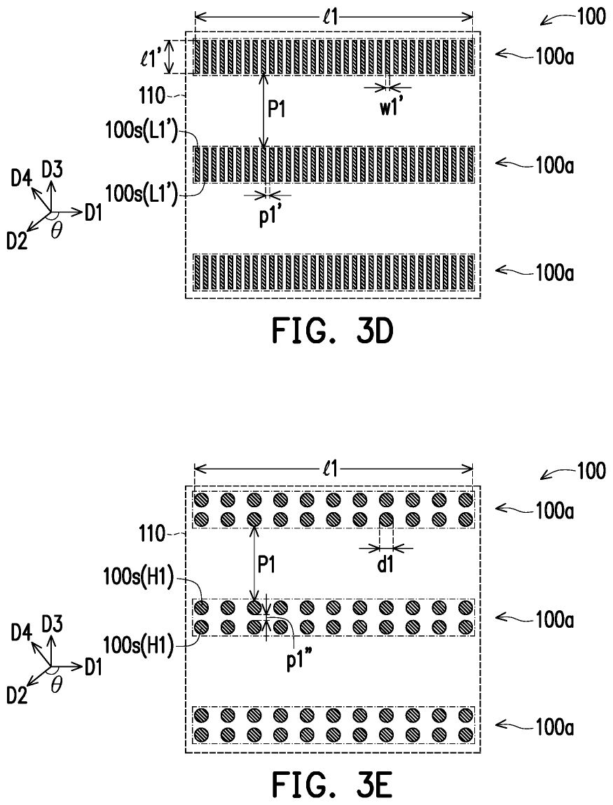

FIG. 3A to FIG. 3E are respectively an enlarged schematic diagram of a first overlay pattern 100a in a partial region 110 according to various embodiments of the present disclosure.

Referring to FIG. 1A and FIG. 3A to FIG. 3E, the first overlay patterns 100a respectively extend along the first direction D1 and the first overlay patterns 100a are arranged along the third direction D3. The first width W1 of the first overlay patterns 100a is approximately equal. The first gap width P1 between the first overlay patterns 100a is approximately equal. The ratio of the first gap width P1 to the first width W1 (P1/W1) ranges from 0.8 to 2.

Each first overlay pattern 100a includes at least one first sub-pattern 100s. Referring to FIG. 1A and FIG. 3A, each first overlay pattern 100a may include three first sub-patterns 100s. However, the embodiment of the disclosure is not limited thereto. Each first overlay pattern 100a may include two first sub-patterns 100s or a single first sub-pattern 100s, as shown in FIG. 3B and FIG. 3C respectively. In other embodiment of the disclosure, each first overlay pattern 100a may include ten or more first sub-patterns 100s, as shown in FIG. 3D and FIG. 3E.

Referring to FIG. 3A to FIG. 3C, the first sub-pattern 100s may be a first line (also referred to as a first trench) L1 extending along the first direction D1. The first line L1 has a width w1 and a length f1. Referring to FIG. 3A and FIG. 3B, in the embodiment in which the first overlay pattern 100a includes a plurality of first sub-patterns 100s, the first lines L1 of the first sub-patterns 100s may respectively extend along the first direction D1 and the first lines L1 of the first sub-patterns 100s may be arranged along the third direction D3. The width w1 of the first lines L1 is approximately equal, and the length f1 of the first lines L1 is approximately equal. The inner gap width p1 between the first sub-patterns 100s (e.g., first lines L1) of each first overlay pattern 100a is approximately equal. The ratio (p1/w1) of the inner gap width p1 to the width w1 ranges, for example, from 0.8 to 1.2.

Referring to FIG. 3D, the first sub-pattern 100s may be a first line (also referred to as a first trench) L1′ extending along the third direction D3. In some embodiments, the first overlay pattern 100a includes a plurality of first sub-patterns 100s. The first lines L1′ of the first sub-patterns 100s may respectively extend along the third direction D3, and the first lines L1′ of the first sub-patterns 100s may be arranged along the first direction D1. The width w1′ of the first lines L1′ is approximately equal, and the length 1′ of the first lines L1′ is approximately equal. The inner gap width p1′ between the first sub-patterns 100s (e.g., first lines L1′) of each first overlay pattern 100a is approximately equal. The first gap width P1 between the first overlay patterns 100a is approximately equal.

Referring to FIG. 3E, the first sub-pattern 100s may include a hole H1. In some embodiments, the first overlay pattern 100a may include a plurality of first sub-patterns 100s, and the holes H1 of the first sub-patterns 100s may be arranged along the first direction D1. The diameter d1 of the holes H1 is approximately equal. The inner gap width p1″ between the first sub-patterns 100s (e.g., holes H1) of each first overlay pattern 100a is approximately equal. The first gap width P1 between the first overlay patterns 100a is approximately equal.

Referring to FIG. 1A, the previous layer mark 1000P further includes a plurality of auxiliary marks 102. The auxiliary marks 102 are respectively disposed in the second sub-region 10B of each first work zone 10. In the embodiment, the previous layer mark 1000P includes four auxiliary marks 102, which are separated by four first marks 100.

Referring to FIG. 1A, the function of the auxiliary pattern 102a of the auxiliary mark 102 is different from that of the first overlay pattern 100a of the first mark 100, and is not used to calculate the overlay error. The auxiliary pattern 102a is an auxiliary pattern used to reduce the load effect. Therefore, the auxiliary pattern 102a may be also referred to as a load effect auxiliary pattern.

In FIG. 1A, the first mark 100 in the first sub-region 10A includes a plurality of first sub-patterns (also referred to as first pattern units) 100s, for example, twenty or more first sub-patterns (or first pattern units) 100s. In each first work zone 10, the first mark 100 in the first sub-region 10A includes eighteen first sub-patterns 100s, and the auxiliary mark 102 in the second sub-region 10B includes more than twenty auxiliary patterns 102a.

The pattern density of the auxiliary mark 102 in the second sub-region 10B of the previous layer mark 1000P is larger than the pattern density of the first mark 100 in the first sub-region 10A of the previous layer mark 1000P. More specifically, the number of auxiliary patterns 102a is larger than the number of first sub-patterns 100s, and the total area of the auxiliary patterns 102a is larger than the total area of first sub-patterns 100s. The pattern density of the auxiliary pattern 102a of the auxiliary mark 102 in the second sub-region 10B is larger than the pattern density of the first overlay pattern 100a of the first mark 100 in the first sub-region 10A.

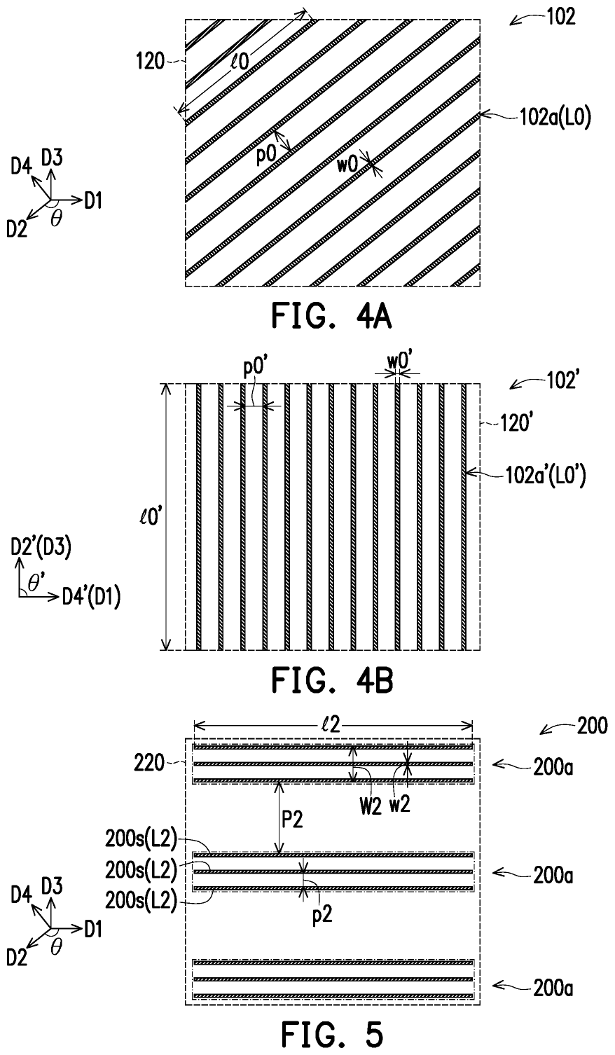

FIG. 4A is an enlarged schematic diagram of the auxiliary mark 102 in a partial region 120 according to various embodiments of the present disclosure.

Referring to FIG. 4A, in the embodiment, the auxiliary pattern 102a includes slanted lines L0. The slanted lines L0 respectively extend along the second direction D2 and are arranged along the fourth direction D4. The second direction D2 is different from the first direction D1, and the fourth direction D4 is also different from the first direction D1. An included angle θ is formed between the second direction D2 and the first direction D1, and θ is defined as, for example, 0<θ<90° or 90°<θ<180°. The width w0 of the slanted lines L0 is approximately equal, and the length f0 may be changed to fill the second sub-region 10B in any suitable way. The gap width p0 between the slanted lines L0 is approximately equal. The ratio of the width w0 to the gap width p0 ranges from 0.8 to 1.2, for example.

Referring to FIG. 3A to FIG. 3E and FIG. 4A, the width w0 of the slanted line L0 may be smaller than, equal to, or larger than the width w1 or w1′ of the first line L1 or L1′. The length f0 of the slanted line L0 may be smaller than, equal to or larger than the length f1 or f1′ of the first line L1 or L1′. The gap width p0 between the slanted line L0 may be smaller than, equal to or larger than the inner gap width p1, p1′ or p1″ of the first line L1, L1′ or hole H1. The gap width p0 between the slanted lines L0 may be smaller than the first gap width P1 between the first lines L1, L1′ or holes H1.

The auxiliary mark 102 of the embodiment of the present disclosure is disposed outside the first mark 100, which may reduce the first mark 100 being affected by the load effect.

The first work zones 10 of the previous layer mark 1000P may have identical first marks 100 and identical auxiliary marks 102. The first mark 100 and the auxiliary mark 102 of one of the first work zones 10 may be rotated by 90 degrees to form the first mark 100 and the auxiliary mark 102 of the adjacent one of the first work zones 10. Therefore, the first marks 100 of the previous layer mark 1000P may be arranged to form a windmill-like shape. The auxiliary marks 102 may be arranged at the periphery of the windmill-like shape formed by the first marks 100.

Referring to FIG. 1B, the current layer mark 1000C includes a plurality of second work zones 20. In FIG. 1B, the current layer mark 1000C includes four second work zones 20, but the disclosure is not limited thereto. The four second work zones 20 are adjacent to one another. Each second work zone 20 includes a first sub-region 20A and a second sub-region 20B. The first sub-region 20A is closer to a center point 20C of the current layer mark 1000C than the second sub-region 20B. In other words, the first sub-regions 20A of the current layer mark 1000C are adjacent to one another, and the second sub-regions 20B of the current layer mark 1000C are separated from each other by the first sub-regions 20A.

Referring to FIG. 1B, the first sub-region 20A of the current layer mark 1000C may form a margin region without disposing any pattern. Second marks 200 may be disposed in the second sub-region 20B of the current layer mark 1000C. The second work zones 20 of the current layer mark 1000C may have identical margin regions and identical second marks 200. The margin region and the second marks 200 of one of the second work zones 20 may be rotated by 90 degrees to form the margin region and the second marks 200 of the adjacent one of the second work zones 20. Therefore, the first sub-regions 20A of the current layer mark 1000C may be arranged to form a windmill-like shaped margin region. The second marks 200 may be arranged at the periphery of the windmill-like shaped margin region.

Referring to FIG. 1B, the second mark 200 of the current layer mark 1000C is used to calculate the overlay error with the first mark 100 of the previous layer mark 1000P (shown in FIG. 1A). Each second mark 200 includes a plurality of second overlay patterns 200a respectively extending along the first direction D1. Each second mark 200 includes six second overlay patterns 200a. However, the embodiment of the present disclosure is not limited thereto. Each second mark 200 may include more second overlay patterns 200a.

FIG. 5 is an enlarged schematic diagram of a second overlay pattern 200a in a partial region 220 according to the embodiment of the present disclosure.

Referring to FIG. 1B and FIG. 5, the second overlay patterns 200a respectively extend along the first direction D1 and are arranged along the third direction D3. Each second overlay pattern 200a includes at least one second sub-pattern 200s. Referring to FIG. 1B, each second overlay pattern 200a may include three second sub-patterns 200s. However, the embodiment of the disclosure is not limited thereto. Each second overlay pattern 200a may include two second sub-patterns 200s or a single second sub-pattern 200s (not shown). In other embodiment of the disclosure, each second overlay pattern 200a may include ten or more second sub-patterns 200s (not shown).

Referring to FIG. 5, the second sub-pattern 200s may be a second line (also referred to as a second trench) L2 extending along the first direction D1. In some embodiments, the second overlay pattern 200a includes a plurality of second sub-patterns 200s, and the second lines L2 of the second sub-pattern 200s may respectively extend along the first direction D1 and may be arranged along the third direction D3. The width w2 of the second lines L2 is approximately equal, and the length f2 of the second lines L2 is approximately equal. The inner gap width p2 between the second sub-patterns 200s (second lines L2) of each second overlay pattern 200a is approximately equal. The second gap width P2 between the second overlay patterns 200a is approximately equal.

Referring to FIG. 4A and FIG. 5, the width w0 of the slanted line L0 may be smaller than, equal to or larger than the second width W2 of the second line L2. The length f0 of the slanted line L0 may be smaller than, equal to or larger than the length f2 of the second line L2. The gap width p0 between the slanted lines L0 may be smaller than, equal to or larger than the inner gap width p2 between the second lines L2. The gap width p0 between the slanted lines L0 may be smaller than the first gap width P2 between the second lines L2.

Referring to FIG. 1A and FIG. 1B, similarly, the pattern density of the auxiliary mark 102 in the second sub-region 10B of the previous layer mark 1000P is larger than the pattern density of the second mark 200 in the second sub-region 20B of the current layer mark 1000C. More specifically, the number of auxiliary patterns 102a is larger than the number of second sub-patterns 200s, and the total area of auxiliary patterns 102a is larger than the total area of the second sub-patterns 200s. The pattern density of the auxiliary pattern 102a of the auxiliary mark 102 in the second sub-region 10B is larger than the pattern density of the second overlay pattern 200a of the second mark 200 in the second sub-region 20B.

Referring to FIG. 1C, the current layer mark 1000C overlaps with the previous layer mark 1000P to form an overlay mark 1000A. In the corresponding first work zone 10 and second work zone 20, the first sub-region 20A of the current layer mark 1000C overlaps with the first sub-region 10A of the previous layer mark 1000P, and the second sub-region 20B of the current layer mark 1000C overlaps with the second sub-region 10B of the previous layer mark 1000P. The overlay error may be calculated by using the second mark 200 in the second sub-region 20B and the first mark 100 in the first sub-region 10A.

FIG. 2 is a schematic diagram of an overlay mark 1000A in a partial region and its signal wave during measurement according to the embodiment of the present disclosure.

Referring to FIG. 2, the overlay errors ΔX and ΔY along X direction and Y direction may be obtained by the peak value of a signal wave 200W of the second overlay patterns 200a of the current layer mark 1000C and the peak value of a signal wave 100W of the first overlay patterns 100a of the previous layer mark 1000P.

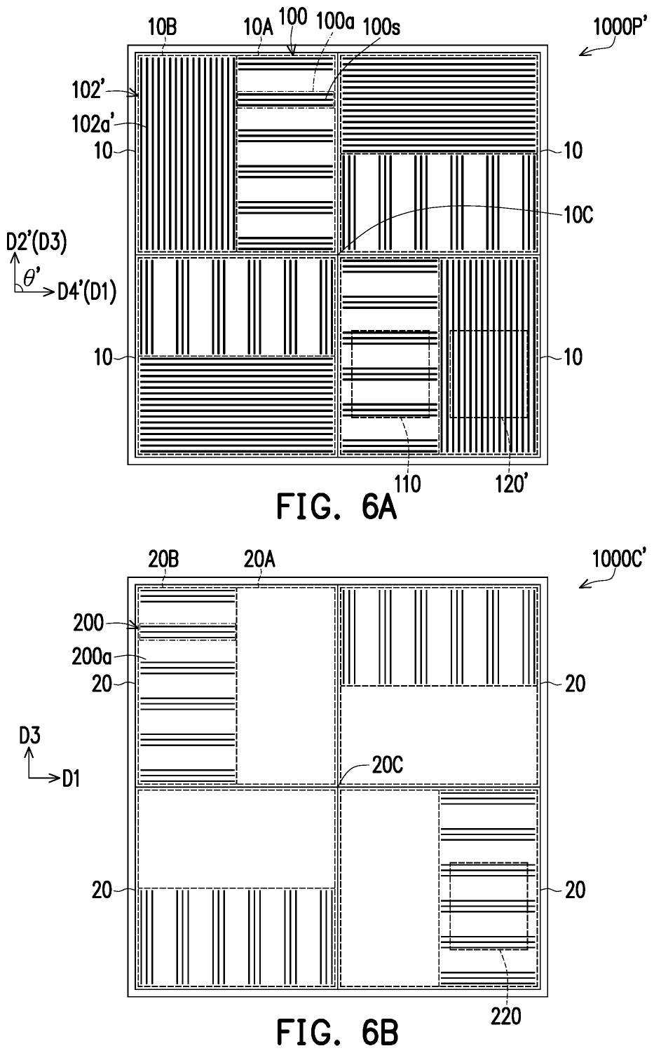

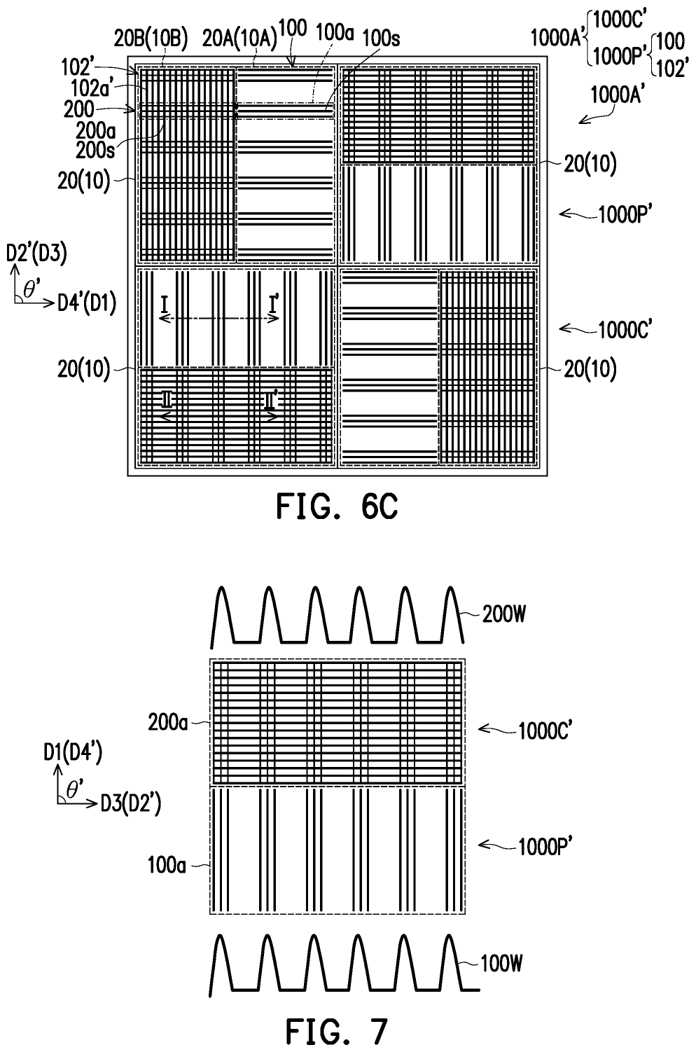

FIG. 6A is a top view of a previous layer mark 1000P′ of an overlay mark 1000A′ according to another embodiment of the present disclosure. FIG. 6B is a top view of a current layer mark 1000C′ of an overlay mark 1000A′ according to another embodiment of the present disclosure. FIG. 6C is a top view of an overlay mark 1000A′ according to another embodiment of the present disclosure.

Referring to FIG. 6A to FIG. 6C, an overlay mark 1000A′ of the embodiment of the present disclosure includes a previous layer mark 1000P′ and a current layer mark 1000C′.

Referring to FIG. 1A and FIG. 6A, the previous layer mark 1000P′ is similar to the previous layer mark 1000P. First marks 100 of the previous layer mark 1000P′ are the same as the first marks 100 of the previous layer mark 1000P, but auxiliary marks 102′ of the previous layer mark 1000P′ are different from the auxiliary marks 102 of the previous layer mark 1000P.

FIG. 4B is an enlarged schematic diagram of an auxiliary mark 102′ in a partial region 120′ according to various embodiments of the present disclosure.

Referring to FIG. 4B and FIG. 6A, the auxiliary marks 102′ are disposed in the second sub-regions 10B. Each auxiliary mark 102′ includes a plurality of auxiliary patterns 102a′. In the embodiment, the auxiliary patterns 102a′ are lines L0′, the lines L0′ respectively extend along the second direction D2′, and the lines L0′ are arranged along the fourth direction D4′. The second direction D2′ is perpendicular to the first direction D1, and the fourth direction D4′ is parallel to the first direction D1.

An included angle θ′ is formed between the second direction D2 and the first direction D1, and θ′ is 90°. The width w0′ of the lines L0′ is approximately equal, and the length f0′ of the lines L0′ is approximately equal. The gap width p0′ between the lines L0′ is approximately equal. The ratio of the width w0′ to the gap width p0′ ranges from 0.8 to 1.2, for example.

Referring to FIG. 3A to FIG. 3E and FIG. 4B, the width w0′ of the line L0′ may be smaller than, equal to, or larger than the width w1 or w1′ of the first line L1 or L1′. The length f0′ of the line L0′ may be smaller than, equal to or larger than the length f1 or f1′ of the first line L1 or L1′. The gap width p0′ between the lines L0′ may be smaller than, equal to or larger than the inner gap width p1, p1′ or p1″ of the first line L1, L1′ or hole H1. The gap width p0′ between the lines L0′ may be smaller than the first gap width P1 between the first lines L1, L1′ or holes H1.

The pattern density of the auxiliary mark 102′ in the second sub-region 10B of the previous layer mark 1000P′ is larger than the pattern density of the first mark 100 in the first sub-region 10A.

Similarly, the auxiliary mark 102′ of the embodiment of the present disclosure is disposed outside the first mark 100, which may reduce the first mark 100 being affected by the load effect.

Referring to FIG. 6B, the current layer mark 1000C′ is similar to the current layer mark 1000C. Likewise, the pattern density of the auxiliary mark 102′ in the second sub-region 10B of the previous layer mark 1000P′ is larger than the pattern density of the second mark 200 in the second sub-region 20B of the current layer mark 1000C′.

Referring to FIG. 6C, the current layer mark 1000C′ overlaps with the previous layer mark 1000P′ to form an overlay mark 1000A′. The overlay error may be calculated by using the second mark 200 in the second sub-region 20B and the first mark 100 in the first sub-region 10A.

FIG. 7 is a schematic diagram of an overlay mark 1000A′ in a partial region and its signal wave during measurement according to another embodiment of the present disclosure.

Referring to FIG. 7, the overlay errors ΔX and ΔY along X direction and Y direction may be obtained by the peak value of a signal wave 200W of the second overlay patterns 200a of the current layer mark 1000C′ and the peak value of a signal wave 100W of the first overlay patterns 100a of the previous layer mark 1000P′.

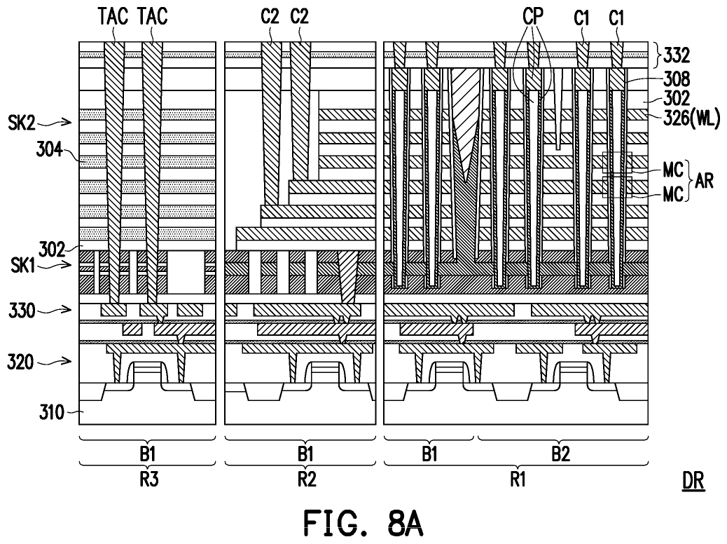

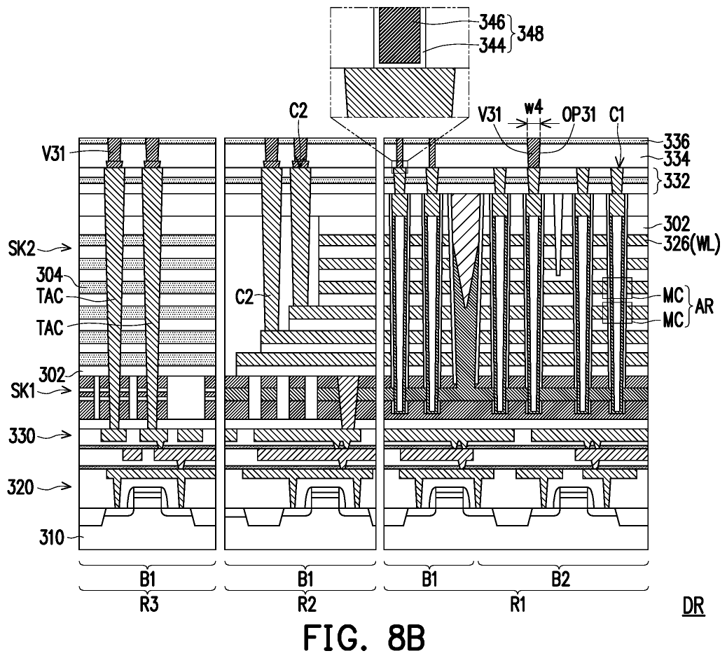

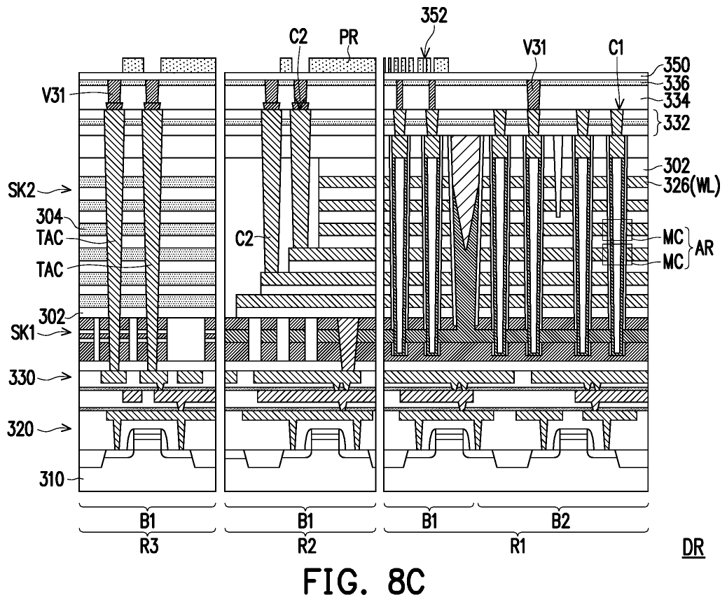

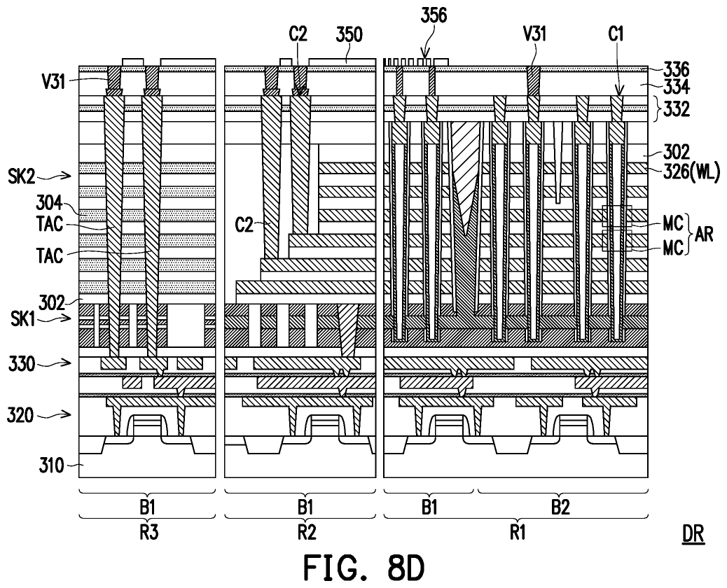

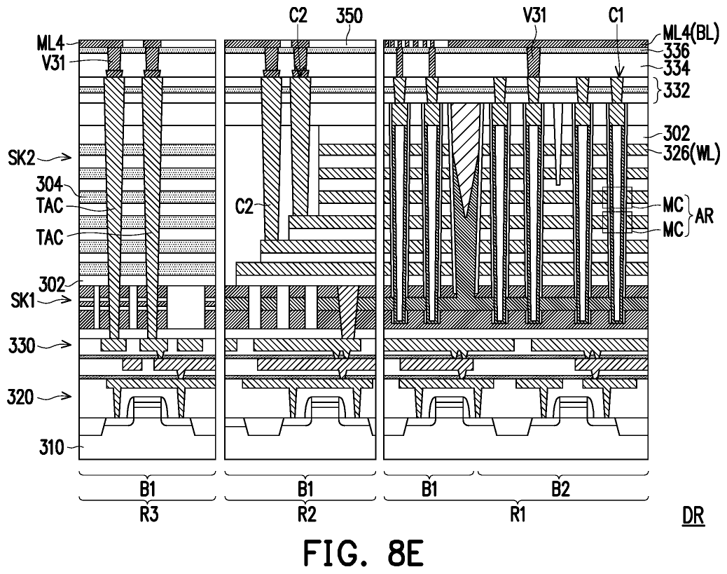

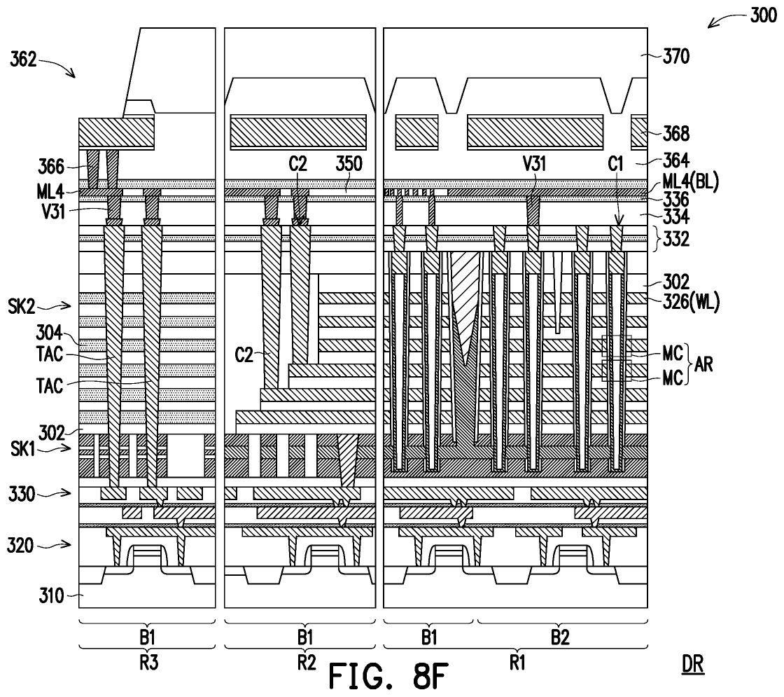

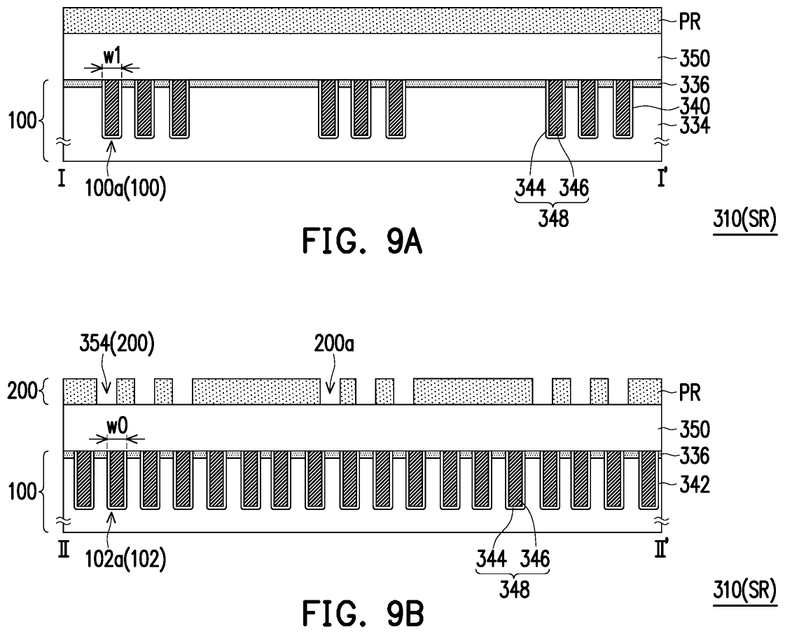

Referring to FIG. 1C and FIG. 6C, the above-mentioned overlay marks 1000A and 1000A′ may be applied in semiconductor devices such as a manufacturing process of a memory device. In the following, the application of the overlay mark 1000A to a manufacturing process of a NAND flash memory device is taken as an example for illustration, but the disclosure is not limited thereto. FIG. 8A to FIG. 8F are schematic cross-sectional views of a manufacturing process of a memory device MD according to the embodiment of the present disclosure. FIG. 9A and FIG. 9B are schematic cross-sectional views along lines I-I′ and II-II′ of FIG. 1C, respectively.

Referring to FIG. 8A and FIG. 9A, a substrate 310 is provided. The substrate 310 includes a chip region DR and a scribe line region SR. The chip region DR includes a memory array region R1, a staircase region R2 and a periphery region R3. The substrate 310 may be a semiconductor substrate, such as a silicon-containing substrate. The substrate 310 may also be divided into blocks B1 and B2. The staircase region R2 and the periphery region R3 are schematic cross-sectional views along one direction, and the memory array region R1 is a schematic cross-sectional view along another direction.

The device layer 320 has been formed on the substrate 310 in the chip region DR. The device layer 320 may include an active device or a passive device. The active device is, for example, a transistor, a diode, and the like. The passive device is, for example, a capacitor, an inductor, and the like. The transistor may be an N-type metal oxide semiconductor (NMOS) transistor, a P-type metal oxide semiconductor (PMOS) transistor, or a complementary metal oxide semiconductor device (CMOS).

A metal interconnect structure 330 has been formed on the substrate 310. The metal interconnect structure 330 overlays the device layer 320. The metal interconnect structure 330 may include a plurality of dielectric layers and a plurality of metal interconnects formed in the dielectric layers. The metal interconnect may be electrically connected to the active device or the passive device of the device layer 320.

A stack structure SK1 has been formed on the metal interconnect structure 330. A portion of the stack structure SK1 includes a plurality of alternating insulating layers and conductive layers. In an embodiment, the material of the insulating layer includes silicon oxide, and the material of the conductive layer includes doped polysilicon. Another portion of the stack structure SK1 includes a plurality of conductive layers connected to one another and serves as a common source line.

A stack structure SK2 has been formed on the stack structure SK1. The stack structure SK2 in the periphery region R3 includes a plurality of alternating insulating layers 302 and middle layers 304. The stack structure SK2 in the memory array region R1 and the staircase region R2 includes a plurality of alternating insulating layers 302 and conductive layers 326. The conductive layer 326 may serve as a word line WL. The insulating layers 302 and the conductive layers 326 in the staircase region R2 may form a staircase structure SC. The material of the insulating layer 302 includes silicon oxide. The material of the middle layer 304 includes silicon nitride. The conductive layer 326 includes, for example, a barrier layer and a metal layer. The material of the barrier layer includes titanium (Ti), titanium nitride (TiN), tantalum (Ta), tantalum nitride (TaN) or a combination thereof, and the material of the metal layer includes tungsten (W).

A plurality of vertical channel pillars CP and a plurality of charge storage structures 308 have been formed in the stack structure SK2. The vertical channel pillar CP includes a polysilicon layer, and the polysilicon layer may wrap a periphery of an insulating pillar. The vertical channel pillar CP may be electrically connected to the conductive layer of the stack structure SK1. The charge storage structure 308 is disposed between the vertical channel pillar CP and the conductive layers 326. The charge storage structure 308 is, for example, an oxide/nitride/oxide (ONO) composite layer. The conductive layer 326, the vertical channel pillar CP and the charge storage structure 308 may together form a memory cell MC. Therefore, the stack structure SK2 may include a memory array AR composed of a plurality of memory cells MC. Since the device layer 320 may include, for example, a CMOS under the memory array, this configuration may be also referred to as CMOS-Under-Array (CUA) structure.

A dielectric layer 332 has been formed on the stack structure SK2. The dielectric layer 332 may be a single layer or a multi-layer. The dielectric layer 332 may include silicon oxide, silicon nitride or a combination thereof. In addition, contacts C1, C2 and TAC have been formed in the dielectric layer 332 and the stack structures SK2 and SK1. The contact C1 lands on the vertical channel pillar CP and is electrically connected to the vertical channel pillar CP. The contact C2 is electrically connected to the conductive layer 326 of the staircase structure SC. The contact TAC may be also referred to as a through array contact. The contact TAC is electrically connected to the metal interconnect structure 330.

Referring to FIG. 8B and FIG. 9A, a dielectric layer 334 and a stop layer 336 are formed on the dielectric layer 332. The dielectric layer 334 may be a single layer or a multi-layer. The dielectric layer 334 includes, for example, silicon oxide. The stop layer 336 includes, for example, silicon nitride. Next, a plurality of vias V31 are formed in the stop layer 336 and the dielectric layer 334 in the chip region DR, as shown in FIG. 8B. Furthermore, a plurality of first overlay patterns 100a of a first mark 100 and a plurality of auxiliary patterns 102a of an auxiliary mark 102 are formed in the stop layer 336 and the dielectric layer 334 in the scribe line region SR, as shown in FIG. 9A and FIG. 9B respectively.

The vias V31, the first overlay patterns 100a and the auxiliary patterns 102a are formed by forming a plurality of via holes OP31 and a plurality of trenches 340 and 342 in the stop layer 336 and the dielectric layer 334, for example. Next, a conductive material (not shown) is formed in the via holes OP31 and the trenches 340 and 342 and on the stop layer 336, and then a planarization process such as a chemical mechanical polishing process is performed to remove the conductive material on the stop layer 336, to form conductive layers 348 in the via holes OP31 and the trenches 340 and 342. The conductive layer 348 may include a barrier layer 344 and a metal layer 346. The barrier layer 344 includes, for example, titanium, TiN, tantalum, tantalum nitride or a combination thereof. The metal layer 346 includes, for example, tungsten. The conductive layers 348 in the via holes OP31 and the trenches 340 and 342 respectively serve as the vias V31, the first overlay patterns 100a and the auxiliary patterns 102a.

In some embodiments, the width w4 of the via hole OP31 is smaller than or equal to 100 nm, and the width w1 of the trench 340 and the width w0 of the trench 342 are respectively smaller than 0.8 m. In the embodiment of the present disclosure, the width w4, w1 and w0 of the via hole OP31 and the trenches 340 and 342 is smaller than or equal to twice the conductive material, so that the conductive layer 348 may fill up the via hole OP31 and the trenches 340 and 342 without leaving a dishing groove in the via hole OP31 and the trenches 340 and 342. If the trench 340 is not filled with the conductive layer 148 and has a dishing groove, it may lead to asymmetry of the conductive layer 348 in the trench 340, thereby causing interference in the subsequent overlay measurement. Since the trench 340 of the present disclosure may be filled with the conductive layer 348, the interference problem caused by the non-completely filling of the conductive layer 348 may be prevented.

Referring to FIG. 8C and FIG. 9A, a cap dielectric layer 350 is formed on the stop layer 336 and the conductive layer 348. The cap dielectric layer 350 is, for example, a silicon oxide layer. After that, a photoresist material is formed on the cap dielectric layer 350. Then, the photolithographic process is performed on the photoresist material to form a patterned photoresist layer PR. A plurality of trenches 352 are formed in the patterned photoresist layer PR in the chip region DR, as shown in FIG. 8C. A plurality of trenches 354 are formed in the patterned photoresist layer PR in the scribe line region SR, as shown in FIG. 9B. The trenches 354 may serve as second overlay patterns 200a. Afterwards, overlay measurement and calculation may be performed by measuring the first overlay patterns 100a and the second overlay patterns 200a, to obtain the overlay error ΔX and ΔY, and then the alignment of the photolithographic process may be determined. If the calculated result is out of the alignment error range, the rework process will be carried out, that is, the photoresist layer PR will be removed and another photoresist layer will be re-formed, and another photolithographic process will be carried out. If the calculated result is within the alignment error range, the subsequent process continues.

Referring to FIG. 8D, using the patterned photoresist layer PR as a mask, the cap dielectric layer 350 is etched to form a trench 356 in the chip region DR, and a trench (not shown) is formed in the cap dielectric layer 350 in the scribe line region SR. For the sake of simplification, the scribe line region SR will not be discussed later.

Referring to FIG. 8E, a conductive material (not shown) is formed in the trenches 356, and then a planarization process such as chemical mechanical polishing is performed, to remove the conductive material on the stop layer 336, and form conductive layers ML4 in the trenches 356. The conductive layer ML4 may include a barrier layer and a metal layer. The barrier layer includes, for example, titanium, TiN, tantalum, tantalum nitride or a combination thereof. The metal layer includes, for example, copper. The conductive layer ML4 is connected to the contact C1 and may serve as a bit line BL.

Referring to FIG. 8F, a metal interconnect structure 362 and a passivation layer 370 are formed. The metal interconnect structure 362 may include a plurality of dielectric layers 364, a plurality of plugs 366, a plurality of conductive lines 368 and so on. The dielectric layer 364 includes, for example, silicon oxide. The passivation layer 370 includes, for example, silicon nitride. So far, the manufacture of the memory device 300 is finished.

In the embodiment of the present disclosure, by using the previous layer mark of the overlay mark, the first overlay pattern is designed as a line (trench) or hole having a smaller width. Thus, the conductive layer may completely fill the line (trench) or hole. Accordingly, the interference caused by non-completely filling of the conductive layer during overlay measurement may be prevented.

Furthermore, the previous layer mark of the overlay mark of the embodiment of the present disclosure is disposed close to the center (e.g., center point) of the overlay mark, and the auxiliary mark is disposed at the periphery of the previous layer mark. The auxiliary design disposed at the periphery of the previous layer mark may reduce the load effect of the polishing process, and reduce or prevent the first overlay pattern being affected by the load effect.

What is claimed is:

1. An overlay mark, comprising:
a previous layer mark, comprising a plurality of first work zones, each first work zone comprising a first sub-region and a second sub-region, the first sub-region being closer to a center point of the previous layer mark than the second sub-region, and the previous layer mark comprising:
a first mark, disposed in the first sub-region of each first work zone; and
an auxiliary mark, disposed in the second sub-region of each first work zone; and
a current layer mark, comprising a plurality of second work zones, each second work zone comprising a first sub-region and a second sub-region, wherein the first sub-region of the current layer mark overlaps with the first sub-region of the previous layer mark, the second sub-region of the current layer mark overlaps with the second sub-region of the previous layer mark, and the current layer mark comprises:
a second mark, disposed in the second sub-region of each second work zone.

2. The overlay mark of claim 1, wherein a pattern density of the auxiliary mark in the second sub-region of the previous layer mark is larger than a pattern density of the first mark in the first sub-region of the previous layer mark.

3. The overlay mark of claim 2, wherein the pattern density of the auxiliary mark in the second sub-region of the previous layer mark is larger than a pattern density of the second mark in the second sub-region of the current layer mark.

4. The overlay mark of claim 1, wherein the auxiliary mark comprises a plurality of auxiliary patterns, and the plurality of auxiliary patterns comprise a plurality of slanted lines.

5. The overlay mark of claim 4, wherein gaps between the plurality of slanted lines are equal.

6. The overlay mark of claim 4, wherein the first mark comprises a plurality of first overlay patterns respectively extending along a first direction, the plurality of slanted lines of the plurality of auxiliary patterns respectively extend along a second direction, and the second direction is different from the first direction.

7. The overlay mark of claim 6, wherein an included angle θ is formed between the second direction and the first direction, and θ is defined as 0<θ<90° or 90°<θ<180°.

8. The overlay mark of claim 6, wherein a first gap is between the plurality of first overlay patterns, and a gap between the plurality of slanted lines of the plurality of auxiliary patterns is smaller than the first gap.

9. The overlay mark of claim 6, wherein the second mark comprises a plurality of second overlay patterns respectively extending along the first direction.

10. The overlay mark of claim 9, wherein each first overlay pattern comprises a single first sub-pattern.

11. The overlay mark of claim 9, wherein each first overlay pattern comprises a plurality of first sub-patterns.

12. The overlay mark of claim 11, wherein the plurality of first sub-patterns comprise a plurality of first lines, and the plurality of first lines respectively extend along the first direction.

13. The overlay mark of claim 11, wherein the plurality of first sub-patterns comprise a plurality of first lines, and the plurality of first lines are arranged along the first direction.

14. The overlay mark of claim 11, wherein the plurality of first sub-patterns comprise a plurality of holes, and the plurality of holes are arranged along the first direction.

15. The overlay mark of claim 9, wherein each second overlay pattern comprises a plurality of second sub-patterns, and the plurality of second sub-patterns comprise a plurality of second lines respectively extending along the first direction.

16. The overlay mark of claim 1, wherein the first marks in the first sub-regions of the first work zones are adjacent to one another.

17. The overlay mark of claim 16, wherein the auxiliary marks in the second sub-regions of the first work zones are separated from each other by the first marks.

18. The overlay mark of claim 17, wherein the second marks in the second sub-regions of the second work zones are separated from each other.

19. The overlay mark of claim 1, wherein the auxiliary pattern is a load effect auxiliary pattern.

20. The overlay mark of claim 1, wherein the first mark comprises a plurality of first overlay patterns respectively extending along a first direction, the auxiliary mark comprises a plurality of auxiliary patterns, the plurality of auxiliary patterns comprise a plurality of lines respectively extending along a second direction, and the second direction is perpendicular to the first direction.
